(19) United States
(12) Patent Application Publication
(10) Pub. No.: US 2012/0042939 A1
(43) Pub. Date: Feb. 23, 2012

(54) ELECTRODE OF SOLAR CELL AND FABRICATION METHOD

(75) Inventor: Tai Hui LIU, Hsinchu County (TW)

(73) Assignee: SOLAPOINT CORPORATION, Hsinchu Country (TW)

(21) Appl. No.: 12/858,297

(22) Filed: Aug. 17, 2010

(51) Int. Cl. H01L 31/0224; H01L 31/18; H01L 31/02

(52) U.S. Cl. 136/256; 438/98; 257/E31.124

(57) ABSTRACT

This invention discloses an electrode of a solar cell electrically connected to a conductive element via a connect structure. The electrode of the solar cell includes a dielectric structure including one or more openings and located on a contact electrode. The connect structure is disposed within the openings to avoid horizontally diffusing into the contact electrode.

### BACKGROUND OF THE INVENTION

1. Field of the Invention

The present invention relates to an electrode of a solar cell and a fabrication method thereof.

2. Description of the Prior Art

Energy generated from solar cells is considered more eco-friendly than other energy sources, such as fossil energy, nuclear energy, water, etc. Lots of advantages of solar power gradually turn up, especially when the crude oil prices continue to shoot up. Furthermore, the crude oil will be exhausted one day, and the solar power, relative to crude oil is concerned the inexhaustible source of energy. Therefore, governments, research institute and many private enterprises have invested many time and resources into solar energy development.

A solar cell is a device that converts the energy of sunlight directly into electricity by the photovoltaic effect. The most commonly known solar cell is configured as a large-area p-n junction made from silicon, germanium, or compounds consisted of two or more elements such as GaAs, and these materials are not conductive. In practice, p-n junctions of silicon solar cells are made by diffusing an n-type dopant into one side of a p-type wafer (or vice versa).

If a piece of p-type silicon is placed in intimate contact with a piece of n-type silicon, then a diffusion of electrons occurs from the region of high electron concentration (the n-type side of the junction) into the region of low electron concentration (p-type side of the junction). When the electrons diffuse across the p-n junction, they recombine with holes on the p-type side. The diffusion of carriers does not happen indefinitely, however, because charges build up on either side of the junction and create an electric field. The electric field creates a diode that promotes charge flow, known as drift current, that opposes and eventually balances out the diffusion of electrons and holes. This region where electrons and holes have diffused across the junction is called the depletion region because it no longer contains any mobile charge carriers. It is also known as the space charge region.

Light, if it includes photons of sufficient energy (greater than the bandgap of the material), creates mobile electron-hole pairs in a semiconductor. Charge separation occurs because of a pre-existing electric field associated with the p-n junction in thermal equilibrium (a contact potential creates the field). This charge separation between positive holes and negative electrons across a p-n junction (a diode), yields a forward voltage, the photo voltage, between the illuminated diode terminals.

Ohmic metal-semiconductor contacts are made to both the n-type and p-type sides of the solar cell, and the electrodes connected to an external load. Electrons that are created on the n-type side, or have been “collected” by the junction and swept onto the n-type side, may travel through the wire, power the load, and continue through the wire until they reach the p-type semiconductor-metal contact. Here, they recombine with a hole that was either created as an electron-hole pair on the p-type side of the solar cell, or a hole that was swept across the junction from the n-type side after being created there.

### SUMMARY OF THE INVENTION

In view of the foregoing, it is an object of the present invention to provide an electrode of a solar cell and fabrication method thereof in order to avoid the solder diffusing into the contact electrode.

Accordingly, the present invention discloses an electrode of a solar cell, and the electrode is electrically connected to a conductive element via a connect structure. The electrode comprises a barrier layer on a contact electrode to avoid the connect structure substantially vertically diffusing into the electrode and the semiconductor structure of the solar cell.

The present invention discloses another electrode of a solar cell, and the electrode is electrically connected to a conductive element via a connect structure. The electrode comprises a dielectric structure with one or more openings, and the dielectric structure is located on a contact electrode. The connect structure is disposed within the openings to avoid substantially horizontally diffusing into the electrode.

In addition, the present invention discloses a fabrication method of an electrode of a solar cell comprising: forming a dielectric structure on a contact electrode; and forming one or more openings at the dielectric structure, wherein the electrode of the solar cell and a conductive element are electrically connected via a connect structure disposed within the openings.

### BRIEF DESCRIPTION OF THE DRAWINGS

The accompanying drawings incorporated in and forming a part of the specification illustrate several aspects of the present invention, and together with the description serve to explain the principles of the disclosure. In the drawings:

FIG. 1 and FIG. 2 show an electrode of a solar cell of the present invention;

FIG. 3 and FIG. 4 show a flow chart of a fabrication method of an electrode of a solar cell of the present invention; and

FIG. 5 shows a flow chart of a fabrication method that a conductive element is electrically connected to an electrode of a solar cell.

### DETAILED DESCRIPTION OF THE PREFERRED EMBODIMENTS

The present disclosure can be described by the embodiments given below. It is understood, however, that the embodiments below are not necessarily limitations to the present disclosure, but are used to a typical implementation of the invention.

Having summarized various aspects of the present invention, reference will now be made in detail to the description of the invention as illustrated in the drawings. While the invention will be described in connection with these drawings, there is no intent to limit it to the embodiment or embodiments disclosed therein. On the contrary the intent is to cover all alternatives, modifications and equivalents included within the spirit and scope of the invention as defined by the appended claims.

It is noted that the drawings presented herein have been provided to illustrate certain features and aspects of embodiments of the invention. It will be appreciated from the description provided herein that a variety of alternative embodiments and implementations may be realized, consistent with the scope and spirit of the present invention.

It is also noted that the drawings presented herein are not consistent with the same scale. Some scales of some components are not proportional to the scales of other components in order to provide comprehensive descriptions and emphases to this present invention.

The present invention provides a fabrication method of an electrode of a solar cell. At first, a dielectric structure is formed on a contact electrode. Next, one or more openings are formed at the dielectric structure. A barrier layer is formed on the contact electrode within the openings after forming the openings. A busbar could be formed on the contact electrode before forming the dielectric structure, wherein the dielectric structure and the barrier layer within the openings are located on the busbar. Alternatively, the busbar could be formed on the contact electrode uncovered in the openings before forming the barrier layer, wherein the barrier layer in the openings is located on the busbar. After forming the barrier layer, another busbar could be formed on the barrier layer in the openings to construct an electrode of a solar cell.

The contact electrode comprises one or any combination selected from the group consisting of Ni, Ag, Al, Cu, Pd, and the barrier layer comprises one or any combination selected from the group consisting of Ti, Cu, W, Mo. The busbars comprises one or any combination selected from the group consisting of Au, Ag, wherein the two busbars could consist of the same or different materials. The dielectric structure comprises one or any combination selected from the group consisting of SiO₂, TiO₂, Al₂O₃, SiN_{X}.

After forming the busbar on the barrier layer, the forming position of the connect structure could be orientated by the openings to form the connect structure at the forming position on the busbar on the barrier layer. The connect structure comprises one or any combination selected from the group consisting of Sn, Al. Then, the conductive element and the connect structure are reflowed by SMT (Surface Mount Technology) to electrically connect the conductive element and the electrode of solar cell. The structure of conductive element comprises a clip or a flexible strip, and material of the conductive element comprises one or any combination selected from the group consisting of Ni, Ag, Al, Cu, Pd.

According to the foregoing fabrication method, a fabrication method of an electrode of a solar cell is provided according to one embodiment of the present invention. At first, a dielectric structure is formed on a contact electrode. Next, one or more openings are formed at the dielectric structure. A busbar is formed on the contact electrode within the openings after forming the openings. Then, a barrier layer is formed on the above-mentioned busbar within the openings to construct one type of the electrode of the solar cell. After forming the barrier layer on the busbar, the connect structure could be orientated at the forming position to be formed on the barrier layer within the openings, wherein the forming position of the connect structure is located at the openings. Later, the conductive element and the electrode of the solar cell are electrically connected by reflowing the conductive element and the connect structure by SMT (Surface Mount Technology).

According to the foregoing fabrication method, a fabrication method of an electrode of a solar cell is provided according to another embodiment of the present invention. At first, a busbar is formed on an electrode. Next, a dielectric structure is formed on the busbar, and one or more openings are formed at the dielectric structure. Then, a barrier layer is formed on the busbar within the openings to construct another type of the electrode of the solar cell. After forming the barrier layer on the busbar, the connect structure could be formed on the forming position on the barrier layer, wherein the forming position of the connect structure is orientated at the openings. Later, the conductive element and the electrode of the solar cell are electrically connected by reflowing the conductive element and the connect structure by SMT.

According to the foregoing fabrication method, a fabrication method of an electrode of a solar cell is provided according to further embodiment of the present invention. At first, a dielectric structure is formed on a contact electrode. Next, one or more openings are formed at the dielectric structure. A barrier layer is formed on the contact electrode within the openings after forming the openings. After forming the barrier layer, a busbar is formed on the barrier layer within the openings to construct further type of the electrode of the solar cell. After forming the busbar on the barrier layer, the forming position of the connect structure could be orientated at the openings to form the connect structure on the busbar within the openings. Later, the conductive element and the electrode of the solar cell are electrically connected by reflowing the conductive element and the connect structure by SMT.

The openings are formed by photolithography and etching method, and the photoresist formed during the photolithography method is striped after forming the openings, forming the barrier layer, forming the busbar on the barrier layer, or forming the connect structure. The connect structure is located in the openings to avoid substantially horizontally diffusing into the electrode, and the connect structure is disconnected from the electrode by the barrier layer to avoid substantially vertically diffusing into the electrode.

The electrode disclosed in the present invention and a solar cell including the electrode could be constructed according to the foregoing fabrication methods. A person having ordinary skill in the art could consider that the solar cell could comprise two or more electrodes disclosed in the present invention.

According to the foregoing fabrication method, an electrode of a solar cell is disclosed in the present invention, wherein the electrode is electrically connected to a conductive element via a connect structure. The electrode of the solar cell comprises a barrier layer located on a contact electrode to avoid the connect structure substantially vertically diffusing into the contact electrode. The electrode of the solar cell further comprises a busbar located between the barrier layer and the contact electrode, or between the connect structure and the barrier layer. Of course, the electrode of the solar cell also could comprise two busbars located respectively between the barrier layer and the contact electrode, and between the connect structure and the barrier layer.

Another electrode of a solar cell is also disclosed in the present invention, wherein the electrode is electrically connected to a conductive element via a connect structure. The electrode of the solar cell comprises a dielectric structure including one or more openings, and the dielectric structure is located on a contact electrode, wherein the connect structure is disposed within the openings to avoid substantially horizontally diffusing into the contact electrode. The electrode of the solar cell further comprises a barrier layer located in the openings and between the connect structure and the contact electrode to avoid the connect structure substantially vertically diffusing into the contact electrode. As above, the electrode of the solar cell further comprises a busbar located between the barrier layer and the contact electrode, or between the connect structure and barrier layer. If the busbar is located between the barrier layer and the contact electrode, the busbar could be on the contact electrode within the openings, or the dielectric structure and the barrier layer within the openings are both located on the busbar. In addition, the electrode of the solar cell also could comprise two busbars respectively located between the barrier layer and the contact electrode, and between the connect structure and barrier layer. Both types of the electrode of the solar cell could be applied to a solar cell to avoid the connect structure diffusing into the contact electrode and the semiconductor of the solar cell. The conductive element could comprise a clip or a flexible strip.

Next, please refer to the drawings to set forth detail, features and embodiments of this invention.

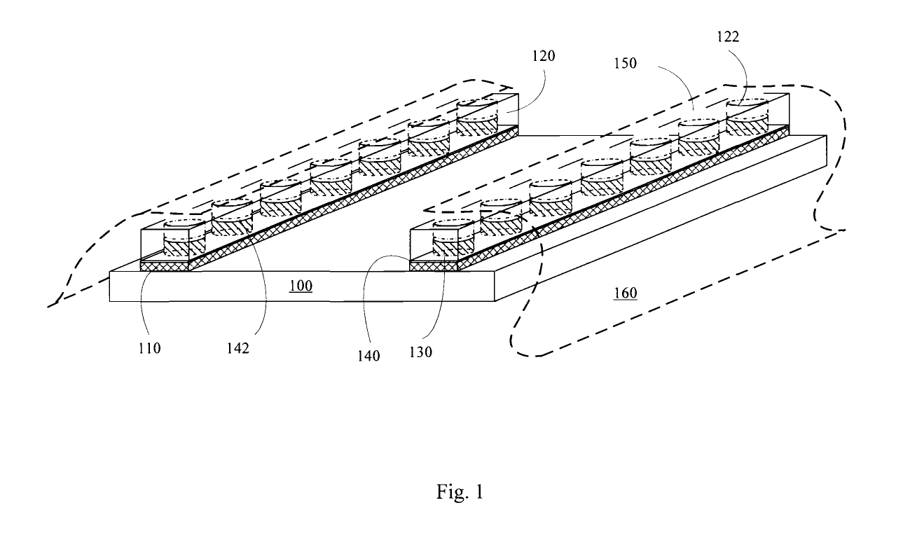

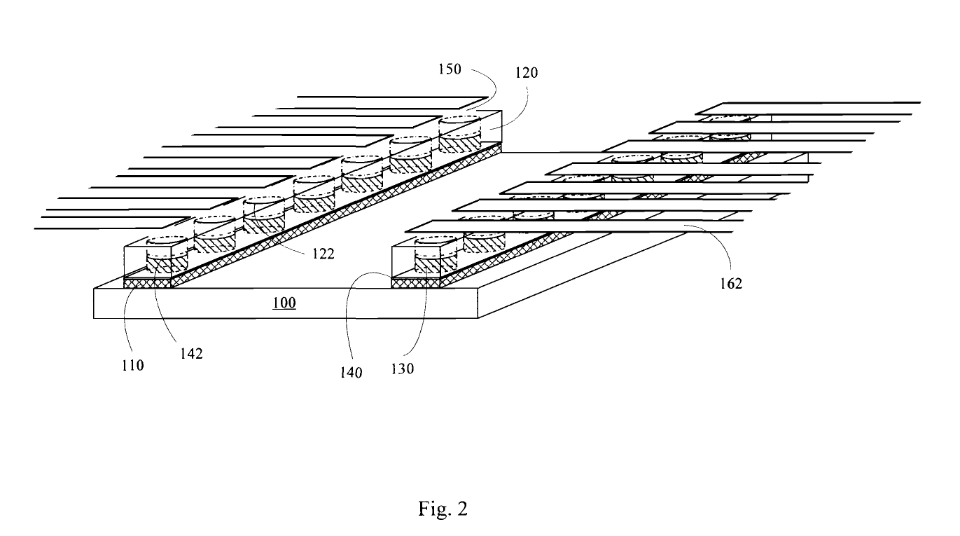

FIG. 1 shows an electrode of a solar cell according to one preferred embodiment of the present invention. The electrode is disposed on a PV (photovoltaic) cell 100, and comprises a contact electrode 110, a dielectric structure 120, a barrier layer 130, and two busbars 140, 142. The dielectric structure 120 includes one or more openings 122. The contact electrode 110 is located between the busbar 140 and the PV cell 100, and the dielectric structure 120 is located on the busbar 140. In the openings 122, the barrier layer 130 is located between two busbars 140, 142. In addition, the electrode is electrically connected to a conductive element via a connect structure 150. The conductive element could be a flexible strip 160 as FIG. 1, or could be a clip 162 as FIG. 2.

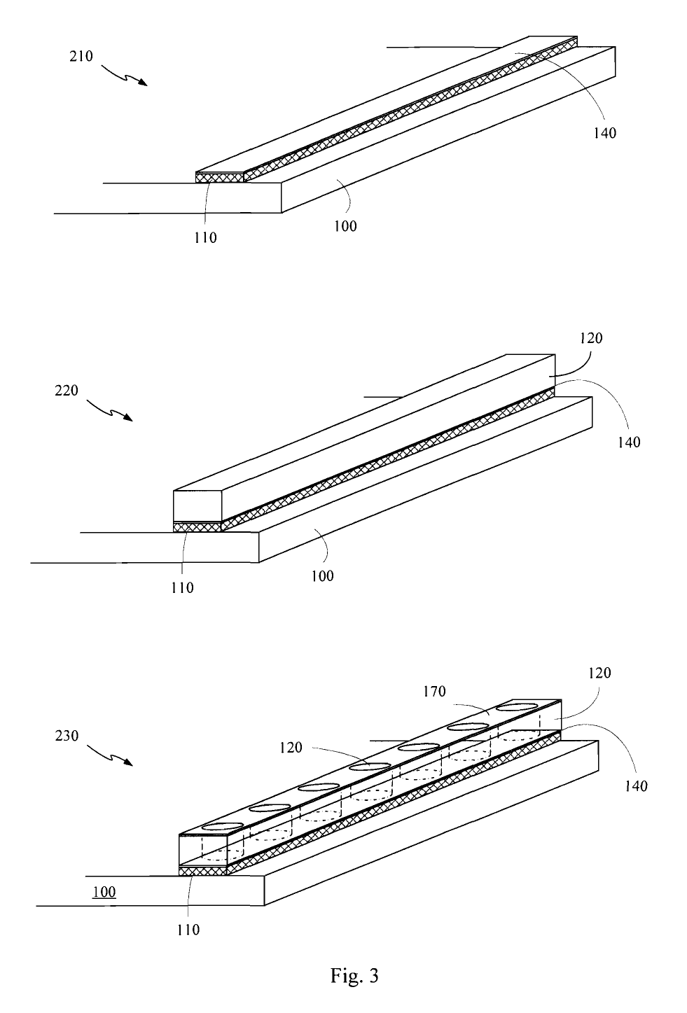

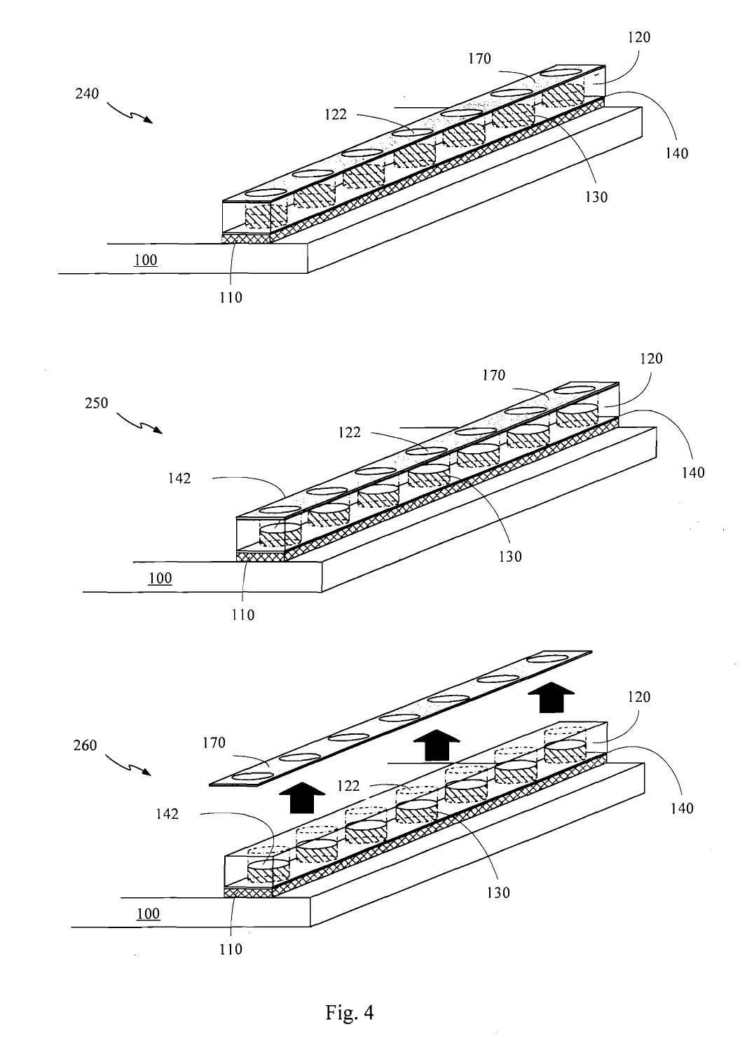

FIG. 3 and FIG. 4 show a flow chart of a fabrication method of the electrode of the solar cell according to another preferred embodiment. At first, as step 210, a busbar 140 is formed on a contact electrode 110, wherein the contact electrode 110 is located on a PV cell 100. Next, as step 220, a dielectric structure 120 is formed on the busbar 140. As step 230, one or more openings 122 are formed at the dielectric structure 120 by the photolithography and etching method after forming a photoresist 170 on the dielectric structure 120. Then, as step 240, a barrier layer 130 is formed on the busbar 140 within the openings 122. Later, as step 250, another busbar 142 is formed the barrier 130 within the openings 122. Finally, as step 260, the foregoing electrode of the solar cell could be constructed after striping the photoresist 170.

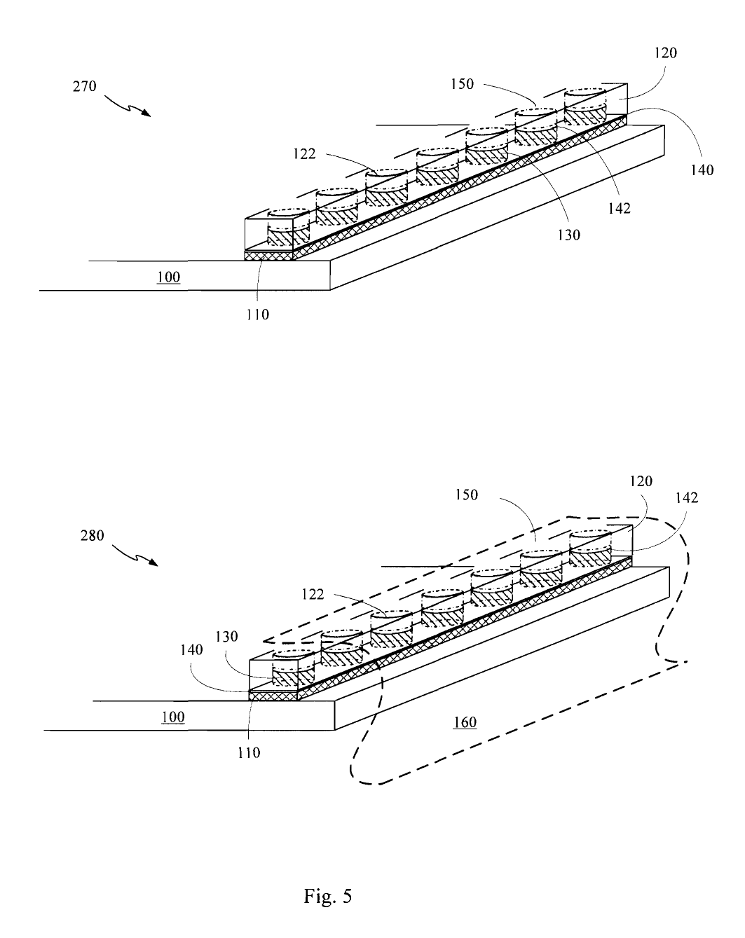

Please refer to FIG. 5, which is a flow chart of a fabrication method that a conductive element is electrically connected to the electrode of the solar cell. As step 270, the forming position of a connect structure 150 is orientated at the openings 122, and then the connect structure 150 is formed on the forming position on the busbar 142 within the openings 122. As step 280, the conductive element and the connect structure 150 are reflowed by SMT to construct a circuit with the external device for producing the electrical energy. The conductive element could be the flexible strip 160 as FIG. 5, or also could be the clip 162 as FIG. 2. In the present embodiment, the busbars 140, 142 comprises silver, and the connect structure 150 comprises solder paste.

Compared with the BGA (Ball Grid Array), bump or clip structure of the traditional electrode of the solar cell, the solder paste of the present invention can be more effectively and exactly orientated at the openings to be uniformly distributed, and can be surrounded and separated respectively by the dielectric structure and the barrier layer in the openings to avoid diffusing into the contact electrode and the semiconductor of the solar cell for increasing the efficiency of the solar cell.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the inventions as determined by the appended claims when interpreted in accordance with the breath to which they are fairly and legally entitled.

It is understood that several modifications, changes, and substitutions are intended in the foregoing disclosure and in some instances some features of the invention will be employed without a corresponding use of other features. Accordingly, it is appropriate that the appended claims be construed broadly and in a manner consistent with the scope of the invention.

1. An electrode of a solar cell, electrically connected to a conductive element via a connect structure, comprising a barrier layer located on a contact electrode to avoid said connect structure diffusing into said contact electrode.

2. An electrode of a solar cell according to claim 1, further comprising a busbar located between said barrier layer and said contact electrode.

3. An electrode of a solar cell according to claim 1, further comprising a busbar located between said connect structure and said barrier layer.

4. A solar cell comprising the electrode of claim 1, wherein said conductive element comprises a clip or a flexible strip.

5. An electrode of a solar cell, electrically connected to a conductive element via a connect structure, comprising a dielectric structure with one or more openings located on a contact electrode, wherein said connect structure is disposed within said openings to avoid diffusing into said contact electrode.

6. An electrode of a solar cell according to claim 5, further comprising a barrier layer within said openings, wherein said barrier layer is located between said connect structure and said contact electrode to avoid said connect structure diffusing into said contact electrode.

7. An electrode of a solar cell according to claim 6, further comprising a busbar located between said connect structure and said barrier layer.

8. An electrode of a solar cell according to claim 6, further comprising a busbar located between said barrier layer and said contact electrode.

9. An electrode of a solar cell according to claim 8, wherein said busbar is located on said contact electrode within said openings, or said dielectric structure and said barrier layer within said openings are located on said busbar.

10. A solar cell comprising the electrode of claim 5, wherein said conductive element comprises a clip or a flexible strip.

11. A fabrication method of an electrode of a solar cell, comprising:
forming a dielectric structure on a contact electrode; and
forming one or more openings at said dielectric structure, wherein said electrode of said solar cell and a conductive element are electrically connected via a connect structure disposed within said openings.

12. A fabrication method of an electrode of a solar cell according to claim 11, after forming said openings, further comprising:
forming a barrier layer on said contact electrode within said openings, wherein said barrier layer comprises one or any combination selected from the group consisting of Ti, Cu, W, Mo.

13. A fabrication method of an electrode of a solar cell according to claim 12, before forming said dielectric structure, further comprising:
forming a busbar on said contact electrode, wherein said dielectric structure and said barrier layer within said openings are located on said busbar, and said busbar comprises one or any combination selected from the group consisting of Au, Ag.

14. A fabrication method of an electrode of a solar cell according to claim 12, before forming said barrier layer, further comprising:
forming a busbar on said contact electrode within said openings, wherein said barrier layer within said openings are located on said busbar, and said busbar comprises one or any combination selected from the group consisting of Au, Ag.

15. A fabrication method of an electrode of a solar cell according to claim 12, after forming said barrier layer, further comprising:
forming a busbar on said barrier layer within said openings, wherein said busbar within said openings comprises one or any combination selected from the group consisting of Au, Ag.

16. A fabrication method of an electrode of a solar cell according to claim 12, after forming said barrier layer, further comprising:
forming said connect structure on the forming position on said barrier layer after orientating the forming position of said connect structure by said openings, wherein said connect structure comprises one or any combination selected from the group consisting of Sn, Al; and
reflowing said conductive element and said connect structure by SMT (Surface Mount Technology) to electrically connect said conductive element and said electrode of solar cell.

17. A fabrication method of an electrode of a solar cell according to claim 16, before forming said connect structure, further comprising:
forming a busbar between said connect structure within said openings and said barrier layer.

18. A fabrication method of an electrode of a solar cell according to claim 17, wherein said openings are formed by photolithography and etching method, and the photoresist formed during the photolithography method is striped after forming said openings, said barrier layer is formed, said busbar on said barrier layer is formed, or said connect structure is formed.

19. A fabrication method of a solar cell comprising the fabrication method of an electrode of a solar cell of claim 11, wherein said dielectric structure comprises one or any combination selected from the group consisting of SiO2, TiO2, Al2O3, SiNX; said conductive element comprises a clip or a flexible strip; said conductive element comprises one or any combination selected from the group consisting of Ni, Ag, Al, Cu, Pd; and said contact electrode comprises one or any combination selected from the group consisting of Ni, Ag, Al, Cu, Pd.

20. A solar cell comprising an electrode of a solar cell manufactured by the fabrication method of claim 11, wherein said dielectric structure comprises one or any combination selected from the group consisting of SiO2, TiO2, Al2O3, SiNX; said conductive element comprises a clip or a flexible strip; said conductive element comprises one or any combination selected from the group consisting of Ni, Ag, Al, Cu, Pd; and said contact electrode comprises one or any combination selected from the group consisting of Ni, Ag, Al, Cu, Pd.
